(19) United States
(12) Patent Application Publication
(10) Pub. No.: US 2026/0020136 A1
(43) Pub. Date: Jan. 15, 2026

(54) DUCT STRUCTURES FOR COOLING OF MEMORY SYSTEM COMPONENTS

(71) Applicant: Micron Technology, Inc., Boise, ID (US)

(72) Inventors: Ramesh Nallavelli, Hyderabad (IN); Hong Wan Ng, Singapore (SG); Yeow Chon Ong, Singapore (SG)

(21) Appl. No.: 19/243,562

(22) Filed: Jun. 19, 2025

Related U.S. Application Data
(60) Provisional application No. 63/669,139, filed on Jul. 9, 2024.

(51) Int. Cl. H05K 1/02

(52) U.S. Cl. CPC H05K 1/0203; H05K 1/0272; H05K 2201/064; H05K 2201/10159

(57) ABSTRACT

Methods, systems, and devices for duct structures for cooling of memory system components are described. For example, a memory system may include multiple memory devices in a first region of the memory system. The memory system may also include circuitry within a second region of the memory system, which may be associated with management of memory device operations. In some examples, the circuitry may be associated with a high operating temperature. The memory system may also include one or more physical ducts made of a material associated with a thermal conductivity that is less than a thermal conductivity of one or more other materials in the memory system. The one or more physical ducts may extend, over a third region of the memory system and between the circuitry and a region associated with a temperature that is less than the operating temperature of the circuitry.

### CROSS REFERENCE

The present application for patent claims priority to U.S. Patent Application No. 63/669,139 by Nallavelli et al., entitled “DUCT STRUCTURES FOR COOLING OF MEMORY SYSTEM COMPONENTS,” filed Jul. 9, 2024, which is assigned to the assignee hereof, and which is expressly incorporated by reference in its entirety herein.

### TECHNICAL FIELD

The following relates to one or more systems for memory, including duct structures for cooling of memory system components.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports duct structures for cooling of memory system components in accordance with examples as disclosed herein.

FIGS. 2 and 3 show examples of architectures that support duct structures for cooling of memory system components in accordance with examples as disclosed herein.

### DETAILED DESCRIPTION

Some memory systems may include multiple components and memory devices associated with varying operating temperatures. In some examples, such as in printed circuitry board assemblies (PCBAs), the components, devices, and other circuitry of the memory system may be located within a relatively small space. Additionally, or alternatively, one or more PCBAs may be coupled (e.g., stacked) together, which may result in a relatively high concentration (e.g., density) of components having varying operating temperatures, which may lead to overheating of the components and associated devices if some type of cooling is not implemented. To help facilitate cooling of the components and memory devices, air flow (e.g., a fan or opening at an edge of a PCBA), heat sinks, or both may be implemented, in some implementations. However, in some examples, space between components or between the PCBAs themselves may inhibit or hinder the use of heat sinks, and heat sinks may otherwise be associated with increased cost and complexity. If a component associated with a relatively high operating temperature (e.g., an average operating temperature over time) is located relatively close to the center of a PCBA, it may be difficult to utilize air from outside the PCBA to cool the component, as the air may be heated over the distance between outside the PCBA and the component and may not effectively cool. Thus, techniques for effective and efficient PCBA component cooling may be beneficial.

To increase efficacy of and efficiency in cooling of components within PCBAs, a physical duct as described herein may be utilized to funnel cool air directly onto components associated with relatively high operating temperatures (e.g., higher than a threshold temperature, higher than operating temperatures of one or more other components in the system). For example, a PCBA may include one or more memory devices in one region and circuitry associated with facilitating operations of the memory devices in another region (e.g., a power management integrated circuit (PMIC), a controller, or other circuitry). In some examples, the circuitry may be associated with a higher operating temperature than the operating temperature of the memory devices. The PCBA may also include one or more physical air ducts that may direct airflow from outside the PCBA to the circuitry (e.g., and other components associated with a high operating temperature). Utilizing a physical duct to direct airflow in cooling operations may improve cooling of components and circuitry associated with high operating temperatures by providing insulation between and facilitating the flow of the cooling air and the rest of the PCBA components, which may result in increased efficiency and operable lifetime of the associated memory devices.

In addition to applicability in memory systems as described herein, techniques for duct structures for cooling of memory system components may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving temperature management within the electronic devices, which may increase the durability and reliability of the electronic devices, thereby supporting increasingly complex applications, among other benefits.

In addition to applicability in memory systems and electronic devices as described herein, techniques for duct structures for cooling of memory system components may also be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving temperature management within the electronic devices, which may increase the durability and reliability of the electronic devices, thereby supporting increasingly complex applications, among other benefits.

Features of the disclosure are illustrated and described in the context of systems and architectures.

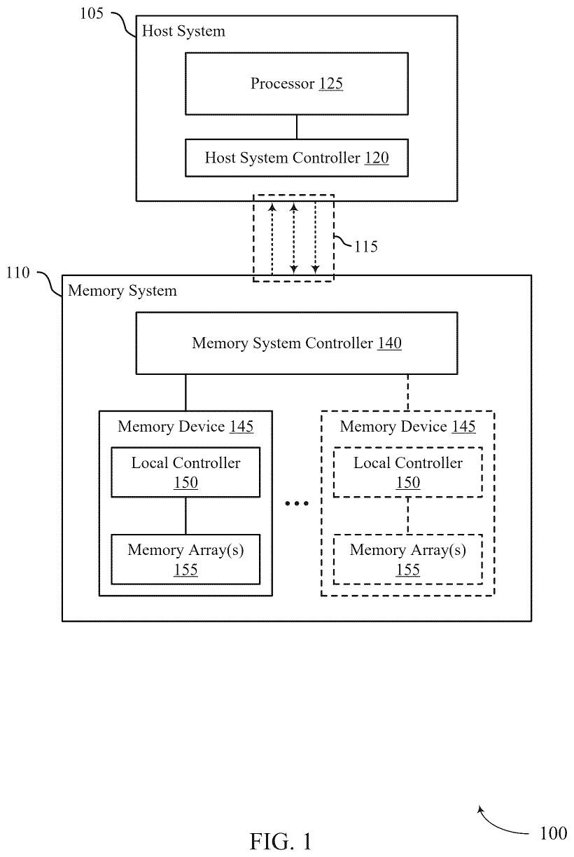

FIG. 1 illustrates an example of a system 100 that supports duct structures for cooling of memory system components in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

In some examples, the memory system 110 may include or be an example of one or more other memory types. For example, the memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. Additionally, or alternatively, the memory devices 145 may include one or more arrays of non-volatile memory cells. For example, a memory device 145 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof.

In some examples, the memory system 110 may include one or more planes of memory. For example, in the case that the memory device 145 may be an example of a NAND device (e.g., an SSD, a UFS device, or another device), the memory devices 145 may include one or more planes of memory. Each plane of memory may include one or more memory blocks, which may include memory cells organized into rows (e.g., pages) and columns (e.g., strings). In some examples, memory cells of a page may share a common word line, while memory cells of a string may share a common digit line, which the memory system 110 may activate to access the memory cell.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

The memory system 110 may include circuitry associated with relatively high operating temperatures. For example, the circuitry may be an example of a power management integrated circuit (PMIC), a controller (e.g., a memory system controller 140, a local controller 150, or some other type of controller), or other circuitry configured to facilitate operations of one or more memory devices 145. In some examples, the circuitry may be coupled with the memory system 110 and may be located in a location that is central to the memory system 110. For example, one or more other components of the memory system 110 (e.g., that may be associated with relatively low operating temperatures, or operating temperatures that may be lower than the operating temperature of the circuitry) may be located around the circuitry. Additionally, or alternatively, the circuitry may be coupled with one or more of the memory devices 145. In some examples, the memory system 110 may also include a heat sink. For example, the memory system 110 may include a heat sink that may be located on or near the circuitry.

The memory system 110 may be located on or may be associated with a substrate. In some examples, the substrate may be an example of or included in a PCBA. For example, the memory system controller 140, the memory devices 145, and other components may be located on a substrate as part of a PCBA. In some examples, each of the memory devices 145 may be associated with a separate PCB (e.g., separate substrates), while, in other examples, each of the memory devices 145 may be associated with a same PCB (e.g., a singular substrate). In the case that the memory system 110 may include a PMIC or other control circuitry, the circuitry may be located near the center or otherwise away from an edge of a top surface of the associated PCB or substrate. That is, at least one other component may be positioned between the circuitry and an edge of the PCB or substrate that is closest to (e.g., in contact with) an external environment.

The memory system 110 may include one or more components and memory devices 145 associated with varying operating temperatures. In some examples, such as in PCBAs, the components, devices, and other circuitry of the memory system may be and located within a relatively small space. In some examples, one or more PCBAs may be coupled (e.g., stacked) together, which may result in a relatively-high concentration of components having varying operating temperatures, which may lead to overheating of the components and associated devices if some type of proper cooling is not implemented. To help facilitate cooling of the components and the memory devices 145 of the PCBA, air flow (e.g., a fan or opening at an edge of a PCBA), heat sinks, or both may be implemented, in some examples. However, in some examples, space between components or between the PCBAs themselves may inhibit the use of heat sinks, or heat sinks may otherwise be associated with increased cost and complexity. If a component associated with a relatively high operating temperature (e.g., an average operating temperature over time) is located relatively close to the center of a PCBA, it may be difficult to utilize air from outside the PCBA to cool the component, as the air may be heated over the distance between outside the PCBA and the component. Thus, techniques for effective and efficient PCBA component cooling may be beneficial.

To increase effectiveness and efficiency in cooling of components within PCBAs, a physical duct as described herein may be utilized to funnel cool air directly onto components associated with relatively high operating temperatures (e.g., higher than a threshold temperature, higher than operating temperatures of other components in the system). For example, a PCBA may include one or more memory devices 145 in one region and circuitry associated with facilitating operations of the memory devices in another region (e.g., a power management integrated circuit (PMIC), a controller, or other circuitry). In some examples, the circuitry may be associated with a higher operating temperature than the operating temperature of the memory devices 145. The PCBA may also include one or more physical air ducts that may direct airflow from outside the PCBA to the circuitry (e.g., and other components associated with a high operating temperature). Utilizing a physical duct to direct airflow in cooling operations may improve cooling of components and circuitry associated with high operating temperatures by providing insulation between the cooling air and the rest of the PCBA components, which may result in increased efficiency and operable lifetime of the associated memory devices 145.

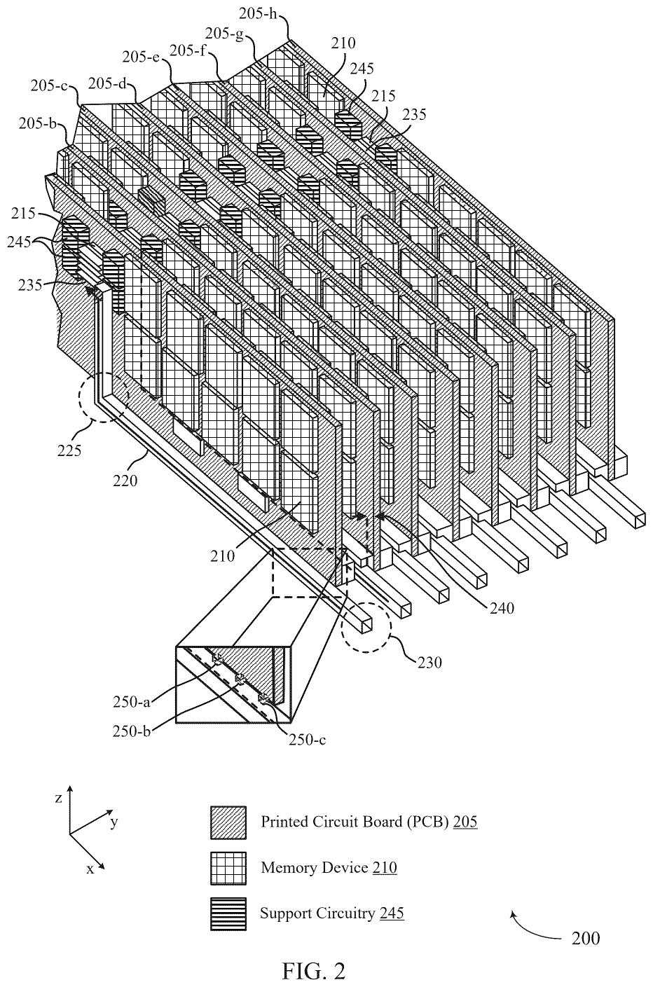

FIG. 2 illustrates an example of an architecture 200 (e.g., a memory architecture) that supports duct structures for cooling of memory system components in accordance with examples as disclosed herein. The architecture 200 may be implemented in or be an example of a memory system 110 or one or more components thereof (e.g., one or more memory devices 145) as described with reference to FIG. 1. Aspects of the architecture 200 may be referred to as or implemented in a PCBA or implemented on a PCB or other substrate.

The architecture 200 may include one or more PCBs 205 (e.g., as further described herein). In some examples, the architecture 200 may include one PCB 205 while, in other examples, the architecture 200 may include multiple PCBs 205 coupled together, such as the PCBs 205-a, 205-b, 205-c, 205-d, 205-e, 205-f, 205-g, and 205-h, as illustrated in FIG. 2. In the case that architecture 200 includes multiple PCBs 205, the PCBs 205 may be coupled together via a layer of bonding material that is associated with relatively low thermal conductivity. Utilizing a bonding material associated with relatively low thermal conductivity may reduce thermal heat transfer from one PCB 205 to another PCB 205 or to a component thereof.

Each PCB 205 may include one or more memory devices 210 and associated circuitry (e.g., support circuitry 245, circuitry 215). For example, each PCB 205 may include one or more memory devices 210 on (e.g., coupled to, bonded with) the surface of each respective PCB 205. In some examples, the memory devices 210 may be examples of memory devices 145 as described with reference to FIG. 1. In the example of FIG. 2, each PCB 205 may include, on a given side of the PCB 205, 10 memory devices 210 on each side of the circuitry 215 in the x-direction (e.g., 20 total memory devices 210 per PCB 205, some of which may not be pictured in FIG. 2). However, it is to be understood that a PCB 205 may include any quantity of memory devices 210 positioned in any pattern, area, or other distribution. The memory devices 210 may be located across various portions (e.g., regions) of each PCB 205. Each of the PCBs 205 may also include the circuitry 215. The circuitry 215 may be an example of a PMIC or other control circuitry (e.g., a memory system controller 140 as described with reference to FIG. 1) associated with facilitating operations of the memory devices 210, and may be coupled with the memory devices 210 of an associated PCB 205 (e.g., via wiring within the PCB 205 or some other electrical connection). The circuitry 215 of a PCB 205 may be located in a portion of the PCB 205 that may be different than the portion of the PCB 205 associated with the memory devices 210. For example, the memory devices 210 of a PCB 205 may be located in (e.g., distributed across, occupy) a first portion or region of the PCB 205 and the circuitry 215 may be located in (e.g., distributed across, occupy) a second portion or region of the PCB 205 that is different from (e.g., nonoverlapping with) the first portion. In some examples, the circuitry 215 may be associated with a higher operating temperature than an operating temperature of the memory devices 210 and other circuitry and components in the memory system. Each PCB 205 may also include support circuitry 245. The support circuitry 245 may be an example of inductors or other support circuitry associated with operations of the memory device 210. In some examples, the PCBs 205 may include one or more other components (e.g., not illustrated).

In some examples, one or more of the PCBs 205 may include at least one heat sink 235. Each heat sink 235 may be located at a position on the associated PCB 205 that may be near the position at which the circuitry 215 may be located (e.g., the heat sinks 235 may be associated with the circuitry 215), near the position at which one or more of the memory devices 210 may be located, or a combination thereof. In some examples, the circuitry 215 may be positioned between the heat sink 235 and the PCB 205. That is, the heat sink 235 may be on top of the circuitry 215, as illustrated in FIG. 2. In such cases, the heat sink 235 may occupy the same first portion or region of the PCB 205 as the circuitry 215. In some examples, each of the heat sinks 235 may be located between support circuitry 245 on the associated PCB 205 along the x-direction. Each heat sink 235 may be configured to reduce the operating temperature of the architecture 200. For example, the architecture 200 may include multiple PCBs 205 extending along (e.g., stacked in) the y-direction that may each include the circuitry 215 and the memory devices 210 associated with varying operating temperatures and located within a relatively small space. In the case that the PCBs 205 may be coupled (e.g., stacked) together, a relatively high concentration of components of varying operating temperatures may result. Because of this relatively high concentration of components, overheating of the components and associated memory devices 210 may occur without the implementation of proper cooling. To help facilitate cooling of the circuitry 215 and the memory devices 210, air flow and heat sinks may be implemented. However, in some examples, space between the various components of the PCBs 205 or between the PCBs 205 themselves may inhibit the use of the heat sinks 235. Additionally, or alternatively, the heat sinks 235 may not sufficiently reduce a temperature of the circuitry 215. If the circuitry 215 (e.g., or another component associated with a high operating temperature) is located relatively close to the center of a PCB 205, as illustrated in FIG. 2, it may be difficult to utilize air from outside the PCB 205 to cool the circuitry 215 as the air may be heated over the distance between outside the PCB 205 and the circuitry 215. Thus, techniques for effective and efficient PCB 205 component cooling may be beneficial.

To increase effectiveness and efficiency in component cooling of PCBs 205, a physical duct 220 may be utilized to funnel cool air directly onto the circuitry 215 and other components of the PCB 205 associated with high operating temperatures. Each PCB 205 may include one or more physical air ducts 220 that may direct airflow from outside the PCB 205 to the circuitry 215 (e.g., and other components associated with a high operating temperature). For example, each PCB 205 may include a physical duct 220 made of material associated with a lower thermal conductivity than the thermal conductivity of the circuitry 215 and the heat sinks 235, to increase cooling and reduce operating temperature of the architecture 200. For example, the physical ducts 220 may be made of fiberglass, polyvinyl chloride (PVC), or another material that has a thermal conductivity that is less than a threshold thermal conductivity to support improved cooling of the memory system.

Each physical duct 220 may be positioned on an associated PCB 205 to direct airflow from outside of the architecture 200 (e.g., outside of the PCBs 205) onto the circuitry 215, the heat sinks 235, the support circuitry 245, or a combination thereof. The physical ducts 220 may be located in a portion or region of the PCB 205 that is different from the portion or regions of the circuitry 215 and the memory devices 210. The physical ducts 220 may extend from an environment that is external to the PCB 205 to the circuitry 215. For example, a physical duct 220 may extend over a portion of the associated PCB 205 along the x-direction such that a first opening (e.g., an inlet 230) of the physical duct 220 may be located outside of or at an edge of the PCB 205, and a second opening (e.g., an outlet) at an opposite end of the physical duct 220 may be located on or near the circuitry 215 (e.g., and the heat sink 235, if included). In some examples, one or more of the physical ducts 220 may be located such that the inlets 230 of the respective physical ducts 220 may be located on alternating or opposite edges of the PCBs 205. For example, while FIG. 2 illustrates the inlets 230 of the physical ducts 220 as being located along the same edge of each of the PCBs 205, in some examples the physical ducts 220 may be positioned such that the inlets 230 may be on different edges of the associated PCBs 205.

The external environment may be an environment that is external to the memory system as a whole (e.g., external to a casing or other enclosure that includes the memory system). Additionally, or alternatively, the external environment may be an environment that is external to at least the PCBs 205, but may include other components associated with the memory system. In some examples, the external environment, may be associated with a user environment, a data center, a server, or the like. A temperature of the external environment may be lower than the operating temperature of the circuitry 215, in most cases. In some examples, the external environment may include a fan or another component to help facilitate airflow via the physical ducts 220. For example, the external environment may include one or more fans that may push air from the external environment through the physical ducts 220 during cooling operations, or the air in the external environment may otherwise flow in one or more directions to facilitate movement of the air toward and into the physical ducts 220.

The physical duct 220 may be located next to one or more of the memory devices 210. For example, the physical duct 220 may be located below one or more of the memory devices 210 in the z-direction and along the x-direction, and may wrap around one or more of the memory devices 210 along the z-direction. In some examples, the physical duct 220 may be positioned in a single direction between a region outside the PCB 205 and the circuitry 215 (e.g., the physical duct 220 may be a straight tunnel). Additionally, or alternatively, the physical duct 220 may include one or more segments each associated with a respective direction and coupled via one or more corners or curves. There may be a gap 240 between the physical duct 220 and the PCB 205 along the y-direction. That is, the physical duct 220 may be offset from the PCB 205 or may otherwise not be in direct contact with the PCB 205 based on one or more supports 250 (e.g., mounts, clips) that facilitate the gap 240. In some examples, the gap 240 may include one or more supports 250 (e.g., a support 250-a, a support 250-b, a support 250-c). The supports 250 may be in direct contact with a respective PCB 205 and an associated physical duct 220 to offset the physical duct 220 from the PCB 205 and facilitate airflow between the physical duct 220 and the PCB 205. One or more of the supports 250 may be dispersed over the length of the physical duct along the x-direction, along the z-direction, or both. The supports 250 may be located between the PCB 205 and the physical duct 220 along the y-direction. The one or more supports 250 may include a material associated with a relatively low thermal conductivity, to reduce heat transfer from the physical ducts 220 to the PCB 205. The gap 240 may be supported by a thermal insulation material and may enable further insulation of the cooling air that flows through the physical duct, such that heat of the architecture 200 and the PCB 205 may have less of an effect on the temperature of the air through the physical duct 220.

Each of the physical ducts 220 may be associated with various forms and openings. For example, each of the physical ducts 220 may include a segment that connects the inlet 230 of the physical duct 220 to the outlet of the physical duct 220. The segment may be an example of a tunnel configured to direct airflow between the inlet 230 and the outlet of the physical duct 220. In some examples, the tunnel may be of a square shape while, in other cases, the tunnel may be cylindrical, or some other shape. The segment (e.g., tunnel) may also include at least one joint 225 that may couple portions of the physical duct 220. For example, the physical duct 220 may include a first portion of the physical duct 220 between the inlet 230 and the joint 225, and a second portion of the physical duct 220 between the outlet of the physical duct 220 and the joint 225. In some examples, the joint 225 may be an example of an angle (e.g., a 90° angle, a 30° angle, or any other angle) while, in other examples, the joint 225 may be an example of one or more curves (e.g., an elbow-shape, an s-shape, a crescent shape, or some other curvature).

The openings of the physical duct 220 may also be of different shapes. For example, the inlet 230 (e.g., and the outlet) may be associated with a square shape, a funnel shape, a circular shape, or another shaped opening. In some examples, the physical duct 220 may also include one or more other openings along the body of the physical duct 220 to direct air transfer onto other components of the PCB 205. For example, the physical duct 220 may include one or more openings in the segment of the physical duct 220 along the x-direction, in the segment of the physical duct 220 along the z-direction, or a combination thereof. The one or more openings may provide air to various regions of the memory system to cool the memory devices 210 and other components of the PCB 205.

The physical ducts 220 may be used in combination with heat sinks 235. For example, the physical ducts 220 may provide relatively cool air to the heat sinks 235, which may further improve performance of the heat sinks 235. Alternatively, the physical ducts 220 may be used to provide cool air directly to the circuitry 215 without the heat sinks 235.

Utilizing the physical ducts 220 to direct airflow from a region exterior to the PCBs 205 to one or more components of each PCB 205 in cooling operations may improve cooling of the memory devices 210 and the circuitry 215 associated with relatively high operating temperatures by providing insulation between the cooling air and the rest of the components of the PCB 205, which may result in increased efficiency and operable lifetime of the architecture 200.

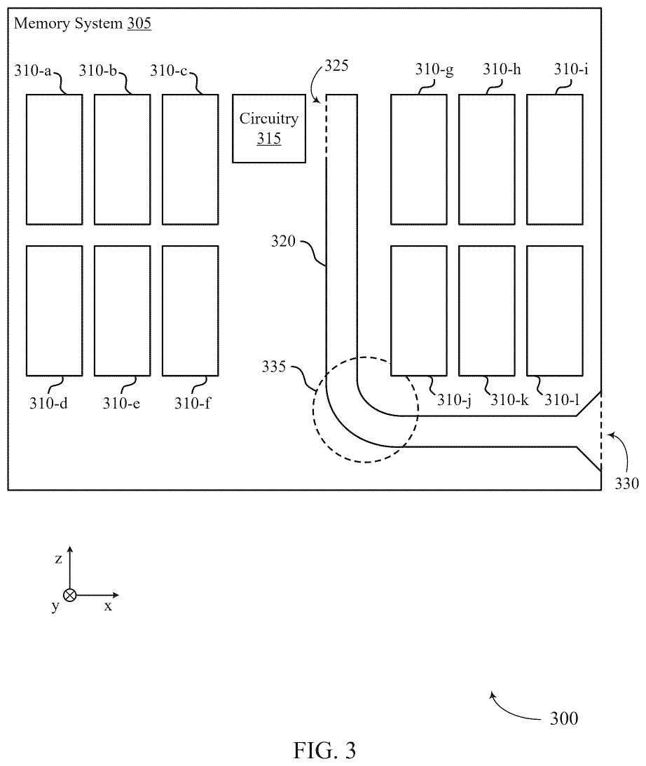

FIG. 3 shows an example of an architecture 300 that supports duct structures for cooling of memory system components in accordance with examples as disclosed herein. The architecture 300 may be implemented in or be an example of a memory system 110 or one or more components thereof (e.g., memory device 145) as described with reference to FIG. 1. In some examples, the architecture 300 may be an example of a PCBA or a PCB 205 as described with reference to FIG. 2.

The architecture 300 may include at least one PCB, which may be at least a portion of a memory system 305, as described herein. The memory system 305 may include one or more memory devices 310. In some examples, the memory devices 310 may be examples of memory devices 145 or memory devices 210, as described with reference to FIGS. 1 and 2, and may be located on the memory system 305 in the xz-plane. The architecture 300 may also include circuitry 315. In some examples, the circuitry 315 may be an example of circuitry as described with reference to FIG. 1, or circuitry 215 as described with reference to FIG. 2, and may be located between one or more memory devices 310 in the xz-plane (e.g., between a first group of memory devices 310-a, 310-b, 310-c, 310-d, 310-e, 310-f and a second group of memory devices 310-g, 310-h, 310-i, 310-j, 310-k, and 310-l in the x-direction). In some examples, the architecture 300 may include one or more heat sinks (e.g., as described herein), which may be located near the circuitry 315 (e.g., below or above the circuitry 315 in the y-direction).

The architecture 300 may include a physical duct 320. The physical duct 320 may be an example of a physical duct 220 as described with reference to FIG. 2. The physical duct 320 may be associated with the memory system 305, and may extend over a region of the memory system 305 that may be different from one or more regions of the memory system 305 that include the memory devices 310 and the circuitry 315. In some examples, the physical duct 320 may be coupled with the memory system 305 while, in other examples, a gap may be located between the physical duct 320 and the memory system 305 along the y-direction, as described with reference to FIG. 2. In some other examples, one or more supports (e.g., clips, mounts) may be located between the physical duct 320 and the memory system 305 along the y-direction, as further described with reference to FIG. 2.

The physical duct 320 may include a first opening (e.g., an inlet 330) that opens towards a region that may be outside the memory system 305 in at least the x-direction (e.g., an external environment). The inlet 330 may be associated with a funnel shape (e.g., or another shape) that may increase in size in the x-direction toward the external environment such that where the inlet 330 connects to the rest of the physical duct 320 may be smaller (e.g., have a smaller diameter or cross-sectional surface area) than the portion of the inlet 330 closer to the exterior region. The physical duct 320 may also include a second opening (e.g., an outlet 325) that opens towards the circuitry 315, a heat sink, one or more of the memory devices 310, or a combination thereof, along the x-direction or along the z-direction, or both. In some examples, the physical duct 320 may also include one or more other openings. For example, the physical duct 320 may include one or more openings near one or more other memory devices 310 along the z-direction or near one or more other memory devices 310 along the x-direction.

The physical duct 320 may bend (e.g., wrap) around one or more memory devices 310 in the xz-plane. For example, the physical duct 320 may include a first segment that extends from the inlet 330 (e.g., from an edge of the memory system 305 or an external environment) to a joint 335. The physical duct 320 may also include a second segment that extends from the joint 335 to the outlet 325. In some examples, the joint 335 may be an example of a segment that connects the first segment of the physical duct 320 and the second segment of the physical duct 320. The joint 335 may be curved or angled (e.g., not illustrated) according to any angle and along any plane or direction. For example, the joint 335 may allow for the physical duct 320 to bend around one or more memory devices 310 from the x-direction to the z-direction.

The memory system 305 may utilize the physical duct 320 to direct airflow from outside the memory system 305 to one or more components (e.g., the circuitry 315, a heat sink, one or more memory devices 310) included on the memory system 305 to cool the components. Utilizing the physical duct 320 to direct airflow from a region exterior to the memory system 305 to one or more components of the memory system 305 in cooling operations may improve cooling of the memory devices 310 and the circuitry 315 associated with high operating temperatures by providing insulation between the cooling air and the rest of the components of the memory system 305, which may result in increased efficiency and operable lifetime of the architecture 200. In some examples, component cooling by the physical duct may be proportional to a size of the physical duct 320. For example, the physical duct 320 may be associated with a size of 2 millimeters (mm) high by 2 mm wide, or some other size. In some examples, a 2 mm×2 mm physical duct 320 may be related to a temperature decrease of ˜5° Celsius, or some other temperature decrease. The effective delta by which the temperature of the circuitry 315 decreases may increase as a size of the physical duct increases, in some examples. Thus, there may be a trade-off between space efficiency and temperature reduction.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A memory system, including: a plurality of memory devices within a first portion of the memory system; circuitry within a second portion of the memory system and associated with management of operations by the plurality of memory devices, where the circuitry is configured to have a first operating temperature that is higher than a second operating temperature of the plurality of memory devices; and one or more physical ducts including material having a first thermal conductivity that is less than a second thermal conductivity of one or more other materials in the memory system, the one or more physical ducts configured to reduce the first operating temperature of the circuitry, where the one or more physical ducts extend, over a third portion of the memory system, between the circuitry and a region associated with a temperature that is less than the first operating temperature and the second operating temperature.

Aspect 2: The memory system of aspect 1, where each physical duct of the one or more physical ducts includes: a first opening at a first end of the physical duct that is closest to the cold air region; a second opening at a second end of the physical duct that is closest to the circuitry; and at least one segment between the first opening and the second opening, the at least one segment including a tunnel shape for air transfer between the first opening and the second opening.

Aspect 3: The memory system of aspect 2, where each physical duct of the one or more physical ducts includes: one or more third openings, within the at least one segment between the first opening and the second opening, to the first portion of the memory system or the second portion of the memory system, the one or more third openings for the air transfer, via the tunnel shape, between the first opening and the first portion of the memory system or between the first opening and the second portion of the memory system.

Aspect 4: The memory system of any of aspects 1 through 3, where each physical duct of the one or more physical ducts includes: a first segment extending from the circuitry in a first direction within the third portion of the memory system; a second segment extending from the region in a second direction within the third portion of the memory system, the second direction different from the first direction; and a third segment coupling the first segment with the second segment.

Aspect 5: The memory system of aspect 4, where the third segment includes a curve or a corner coupled between the first direction of the first segment and the second direction of the second segment.

Aspect 6: The memory system of any of aspects 1 through 5, where each physical duct of the one or more physical ducts includes: a segment extending from the circuitry to the region in a single direction within the third portion of the memory system, the segment including one or more openings to the region and the circuitry.

Aspect 7: The memory system of any of aspects 1 through 6, where each physical duct of the one or more physical ducts includes: a funnel shaped opening at a first end of the physical duct that is closest to the region associated with the temperature that is less than the first operating temperature and the second operating temperature, where a width of the funnel shaped opening increases from a first width to a second width that is greater than the first width within the first end of the physical duct.

Aspect 8: The memory system of any of aspects 1 through 7, further including: one or more PCBs, where the plurality of memory devices is located on the one or more PCBs and the one or more physical ducts are offset from the one or more PCBs by one or more gaps comprising a thermal insulation material, the one or more gaps extending along the third portion of the memory system between each physical duct of the one or more physical ducts and the one or more PCBs.

Aspect 9: The memory system of any of aspects 1 through 8, where the one or more physical ducts extend over the third portion of the memory system and between the region and the circuitry according to a curvature, an angle, or a combination thereof.

Aspect 10: The memory system of any of aspects 1 through 9, where the circuitry includes a power management integrated circuitry associated with the plurality of memory devices.

Aspect 11: The memory system of any of aspects 1 through 10, where the circuitry includes a controller for the memory system.

Aspect 12: The memory system of any of aspects 1 through 11, where the material includes fiberglass or polyvinyl chloride (PVC).

Aspect 13: The memory system of any of aspects 1 through 12, where the region is external to the memory system.

An apparatus is described. The following provides an overview of aspects of the apparatus as described herein:

Aspect 14: A memory system, including: a plurality of memory devices within a first portion of the memory system; circuitry configured to facilitate operations by the plurality of memory devices and within a second portion of the memory system, where the circuitry is configured to have a first operating temperature that is higher than a second operating temperature of the plurality of memory devices; one or more heat sinks coupled with the circuitry; and one or more physical ducts coupled with the one or more heat sinks and configured to move air from a region associated with a temperature that is less than the first operating temperature and the second operating temperature to the one or more heat sinks, where the one or more physical ducts are associated with a third portion of the memory system that is different from the first portion and the second portion.

Aspect 15: The memory system of aspect 14, further including: one or more PCBs, where the circuitry is positioned between the one or more heat sinks and a PCB of the one or more PCBs within the second portion of the memory system.

Aspect 16: The memory system of any of aspects 14 through 15, where the one or more heat sinks are configured to reduce the first operating temperature of the memory system based at least in part on the air transferred to the one or more heat sinks from the region via the one or more physical ducts.

Aspect 17: The memory system of any of aspects 14 through 16, where each physical duct of the one or more physical ducts includes: a funnel shaped opening towards the region associated with the temperature that is less than the first operating temperature and the second operating temperature, where a width of the funnel shaped opening increases from a first width to a second width that is greater than the first width within a region of each duct that is closest to the region.

Aspect 18: The memory system of any of aspects 14 through 17, where each physical duct of the one or more physical ducts includes: a first segment extending in a first direction within the third portion of the memory system; a second segment extending in a second direction within the third portion of the memory system, the second direction that is different from the first direction; and a third segment coupling the first portion with the second portion.

Aspect 19: The memory system of aspect 18, where the third segment includes a curve or a corner coupled between the first segment in the first direction and the second segment in the second direction.

Aspect 20: The memory system of any of aspects 14 through 19, where each physical duct of the one or more physical ducts includes: a first opening to the region; a second opening to the circuitry; and a segment between the first opening and the second opening, the segment including a tunnel shape for movement of the air between the first opening and the second opening.

Aspect 21: The memory system of aspect 20, where each physical duct of the one or more physical ducts includes: one or more openings, within the segment between the first opening and the second opening, to the first portion of the memory system or the second portion of the memory system, the one or more openings for the movement of the air, via the tunnel shape, between the first opening and the first portion of the memory system or between the first opening and the second portion of the memory system.

An apparatus is described. The following provides an overview of aspects of the apparatus as described herein:

Aspect 22: A memory system, including: one or more PCBs; and a plurality of memory devices distributed across the one or more PCBs, where each PCB of the one or more PCBs includes: one or more memory devices positioned within a first region of the PCB; circuitry associated with the one or more memory devices and positioned within a second region of the PCB, where a portion of the circuitry is associated with a first temperature characteristic that is greater than other temperature characteristics associated with the one or more memory devices; and one or more ducts coupled with the portion of the circuitry, where each duct extends from the portion of the circuitry to a fourth region that is external to the memory system and across a third region of the PCB that is different from the first region including the one or more memory devices and the second region including the circuitry.

Aspect 23: The memory system of aspect 22, where the one or more ducts of a first PCB of the one or more PCBs are offset from the first PCB by a first gap region and are offset from a second PCB of the one or more PCBs by a second gap region, the second PCB adjacent to the first PCB.

Aspect 24: The memory system of any of aspects 22 through 23, where each duct of the one or more ducts includes: a first opening at a first end of the duct that is closest to the fourth region; a second opening at a second end of the duct that is closest to the circuitry; and at least one segment between the first opening and the second opening, the at least one segment including a tunnel shape for air transfer between the first opening and the second opening.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a plurality of memory devices within a first portion of the memory system;
circuitry within a second portion of the memory system and associated with management of operations by the plurality of memory devices, wherein the circuitry is configured to have a first operating temperature that is higher than a second operating temperature of the plurality of memory devices; and
one or more physical ducts comprising material having a first thermal conductivity that is less than a second thermal conductivity of one or more other materials in the memory system, the one or more physical ducts configured to reduce the first operating temperature of the circuitry, wherein the one or more physical ducts extend, over a third portion of the memory system, between the circuitry and a region associated with a temperature that is less than the first operating temperature and the second operating temperature.

2. The memory system of claim 1, wherein each physical duct of the one or more physical ducts comprises:
a first opening at a first end of the physical duct that is closest to the region associated with cold air;
a second opening at a second end of the physical duct that is closest to the circuitry; and
at least one segment between the first opening and the second opening, the at least one segment comprising a tunnel shape for air transfer between the first opening and the second opening.

3. The memory system of claim 2, wherein each physical duct of the one or more physical ducts comprises:
one or more third openings, within the at least one segment between the first opening and the second opening, to the first portion of the memory system or the second portion of the memory system, the one or more third openings for the air transfer, via the tunnel shape, between the first opening and the first portion of the memory system or between the first opening and the second portion of the memory system.

4. The memory system of claim 1, wherein each physical duct of the one or more physical ducts comprises:
a first segment extending from the circuitry in a first direction within the third portion of the memory system;
a second segment extending from the region in a second direction within the third portion of the memory system, the second direction different from the first direction; and
a third segment coupling the first segment with the second segment.

5. The memory system of claim 4, wherein the third segment comprises a curve or a corner coupled between the first direction of the first segment and the second direction of the second segment.

6. The memory system of claim 1, wherein each physical duct of the one or more physical ducts comprises:
a segment extending from the circuitry to the region in a single direction within the third portion of the memory system, the segment comprising one or more openings to the region and the circuitry.

7. The memory system of claim 1, wherein each physical duct of the one or more physical ducts comprises:
a funnel shaped opening at a first end of the physical duct that is closest to the region associated with the temperature that is less than the first operating temperature and the second operating temperature, wherein a width of the funnel shaped opening increases from a first width to a second width that is greater than the first width within the first end of the physical duct.

8. The memory system of claim 1, further comprising:
one or more printed circuit boards (PCBs), wherein the plurality of memory devices is located on the one or more PCBs and the one or more physical ducts are offset from the one or more PCBs by one or more gaps comprising a thermal insulation material, the one or more gaps extending along the third portion of the memory system between each physical duct of the one or more physical ducts and the one or more PCBs.

9. The memory system of claim 1, wherein the one or more physical ducts extend over the third portion of the memory system and between the region and the circuitry according to a curvature, an angle, or a combination thereof.

10. The memory system of claim 1, wherein the circuitry comprises a power management integrated circuitry associated with the plurality of memory devices.

11. The memory system of claim 1, wherein the circuitry comprises a controller for the memory system.

12. The memory system of claim 1, wherein the material comprises fiberglass or polyvinyl chloride (PVC).

13. The memory system of claim 1, wherein the region is external to the memory system.

14. A memory system, comprising:
a plurality of memory devices within a first portion of the memory system;
circuitry configured to facilitate operations by the plurality of memory devices and within a second portion of the memory system, wherein the circuitry is configured to have a first operating temperature that is higher than a second operating temperature of the plurality of memory devices;
one or more heat sinks coupled with the circuitry; and
one or more physical ducts coupled with the one or more heat sinks and configured to move air from a region associated with a temperature that is less than the first operating temperature and the second operating temperature to the one or more heat sinks, wherein the one or more physical ducts are associated with a third portion of the memory system that is different from the first portion and the second portion.

15. The memory system of claim 14, further comprising:
one or more printed circuit boards (PCBs), wherein the circuitry is positioned between the one or more heat sinks and a PCB of the one or more PCBs within the second portion of the memory system.

16. The memory system of claim 14, wherein the one or more heat sinks are configured to reduce the first operating temperature of the memory system based at least in part on the air transferred to the one or more heat sinks from the region via the one or more physical ducts.

17. The memory system of claim 14, wherein each physical duct of the one or more physical ducts comprises:
a funnel shaped opening towards the region associated with the temperature that is less than the first operating temperature and the second operating temperature, wherein a width of the funnel shaped opening increases from a first width to a second width that is greater than the first width within a respective region of each duct that is closest to the region.

18. The memory system of claim 14, wherein each physical duct of the one or more physical ducts comprises:
a first segment extending in a first direction within the third portion of the memory system;
a second segment extending in a second direction within the third portion of the memory system, the second direction that is different from the first direction; and
a third segment coupling the first portion with the second portion.

19. The memory system of claim 18, wherein the third segment comprises a curve or a corner coupled between the first segment in the first direction and the second segment in the second direction.

20. The memory system of claim 14, wherein each physical duct of the one or more physical ducts comprises:
a first opening to the region;
a second opening to the circuitry; and
a segment between the first opening and the second opening, the segment comprising a tunnel shape for movement of the air between the first opening and the second opening.

21. The memory system of claim 20, wherein each physical duct of the one or more physical ducts comprises:
one or more openings, within the segment between the first opening and the second opening, to the first portion of the memory system or the second portion of the memory system, the one or more openings for the movement of the air, via the tunnel shape, between the first opening and the first portion of the memory system or between the first opening and the second portion of the memory system.

22. A memory system, comprising:
one or more printed circuit boards (PCBs); and
a plurality of memory devices distributed across the one or more PCBs, wherein each PCB of the one or more PCBs comprises:
one or more memory devices positioned within a first region of the PCB;
circuitry associated with the one or more memory devices and positioned within a second region of the PCB, wherein a portion of the circuitry is associated with a first temperature characteristic that is greater than other temperature characteristics associated with the one or more memory devices; and
one or more ducts coupled with the portion of the circuitry, wherein each duct extends from the portion of the circuitry to a fourth region that is external to the memory system and across a third region of the PCB that is different from the first region comprising the one or more memory devices and the second region comprising the circuitry.

23. The memory system of claim 22, wherein the one or more ducts of a first PCB of the one or more PCBs are offset from the first PCB by a first gap region and are offset from a second PCB of the one or more PCBs by a second gap region, the second PCB adjacent to the first PCB.

24. The memory system of claim 22, wherein each duct of the one or more ducts comprises:
a first opening at a first end of the duct that is closest to the fourth region;
a second opening at a second end of the duct that is closest to the circuitry; and
at least one segment between the first opening and the second opening, the at least one segment comprising a tunnel shape for air transfer between the first opening and the second opening.
